(19) United States
(12) Patent Application Publication
(10) Pub. No.: US 2016/0100479 A1
(43) Pub. Date: Apr. 7, 2016

(54) DISPLAY DEVICE

(71) Applicant: E.G.O. Elektro-Geraetebau GmbH, Oberderdingen (DE)

(72) Inventor: Micha Henrich, Eppingen (DE)

(21) Appl. No.: 14/872,850

(22) Filed: Oct. 1, 2015

(30) Foreign Application Priority Data
Oct. 6, 2014 (DE) 10 2014 220 188.8

(51) Int. Cl. H05K 1/02; H05K 1/09; F21V 23/00; H05K 1/18

(52) U.S. Cl. CPC H05K 1/0274; H05K 1/181; H05K 1/09; H05K 1/0296; F21V 23/00; H05K 2201/10106; F21Y 2101/02

(57) ABSTRACT

The invention relates to a display device including a printed circuit board and a number of light-emitting diodes, wherein a structured copper coating is provided on the printed circuit board. The copper coating has shielding regions which reduce or prevent penetration of light emitted downwards from the light-emitting diodes into the printed circuit board. This reduces or prevents emergence of light from the printed circuit board again at undesired locations.

### CROSS-REFERENCE TO RELATED APPLICATIONS

This application claims priority to German Application No. 10 2014 220 188.8, filed Oct. 6, 2014, the contents of which are hereby incorporated herein in its entirety by reference.

### TECHNOLOGICAL FIELD

The invention relates to a display device for a domestic appliance, in particular for a hob or an oven.

### BACKGROUND

Such display devices are known from DE 102012219040 A1 or U.S. Pat. No. 5,917,165 A. They can be used for example for various domestic appliances such as hobs, ovens or microwave appliances. The light-emitting diodes are often arranged such that they jointly form a seven-segment display. In order that information communicated to a user by the display device via the light-emitting diodes can readily be read and, furthermore, a design that is aesthetically appealing to a certain extent is also achieved, it is advantageous if, as far as possible, light emitted by the light-emitting diodes is only emitted in a defined direction. This direction often runs at right angles to a plane defined by the printed circuit board.

It has been found, however, that light-emitting diodes usually emit light not only in a desired direction, but in particular also in a direction towards the printed circuit board, albeit with a lower intensity. Printed circuit boards usually used are produced from a material containing light-guiding fibres, for example optical fibres. This can have the effect that light penetrates into the printed circuit board below a light-emitting diode, passes in such a light-guiding fibre to a different location on the surface of the printed circuit board and emerges again there. This can lead to undesired and disturbing additional light phenomena.

Furthermore, light-scattering material of luminous caps or light channels arranged above the LEDs ensures that part of the light emitted upwards is also guided downwards again in the direction of the printed circuit board. Although this material property of the luminous caps or light channels absorbs light portions as a type of diffuser it is necessary for better illumination of symbols or the like arranged thereabove.

### BRIEF SUMMARY

The invention addresses the problem of providing a display device mentioned in the introduction with which problematic issues in the prior art are avoided and it is possible, in particular, to avoid stray light or undesired light phenomena.

This problem is solved by means of a display device. Advantageous and preferred embodiments of the invention are the subject matter of the further claims and are explained in greater detail below. The wording of the claims is expressly incorporated by reference in the content of the description.

The display device comprises a printed circuit board or a component carrier having a structured copper coating, advantageously a customary printed circuit board having optical fibres embedded into a resin, with a customary copper coating applied on the printed circuit board, in particular on a top side. In the case of printed circuit boards in accordance with the prior art, such a copper coating has the function of connecting specific components or electrically earthing regions of the printed circuit board, in particular with conductor tracks in each case. A number of contact zones are defined on the printed circuit board or on the copper coating, which contact zones are connected in particular to conductor tracks in each case. The latter can be used for connecting electrical components on the top side.

The display device furthermore comprises a number of light-emitting diodes as abovementioned components on the top side. Each light-emitting diode has a first terminal and a second terminal. These terminals enable the electrical contacting of the light-emitting diode for the electrical supply or driving thereof. The light-emitting diodes are mounted and electrically connected on the printed circuit board in such a way that each terminal is fixed to a respectively assigned contact zone.

An intermediate surface of the printed circuit board is formed between respectively two contact zones to which the two terminals of a single light-emitting diode are fixed, the intermediate surface being covered by the light-emitting diode. It should be mentioned that, in particular, light which emerges from the light-emitting diode in a direction towards the printed circuit board can penetrate into the printed circuit board, in principle, in the intermediate surface. That also applies to the abovementioned effect that light is guided in part downwards again in the direction of the printed circuit board by luminous caps or light channels arranged above the LEDs. This may be the case, in particular, if the printed circuit board contains light-guiding fibres, for example optical fibres, which are embedded into a resin. This is the case for example for a material that is frequently used and is typically designated as FR4.

The invention provides for the copper coating to have a number of shielding regions which at least partly cover an intermediate surface in each case, that is to say advantageously one shielding surface per intermediate surface or per light-emitting diode. The shielding regions are therefore shaped from or formed by the copper coating, advantageously with the same thickness of the copper coating also in the other regions. By means of the shielding regions, light is prevented from penetrating below the light-emitting diode or from the underside thereof into the printed circuit board since the copper coating is non-transmissive to light. This also applies to light which is guided outside or alongside the LED and possibly below an abovementioned luminous cap or light channel downwards. Since the light does not actually penetrate into the printed circuit board at all, it cannot emerge from the latter anywhere else either. If the shielding regions are only suitable for reducing the entry of light instead of completely preventing it, for example because they do not cover the entire area below the light-emitting diode, they can still reduce disturbing effects. Furthermore, the dissipation of heat loss from the LED can possibly also be improved via the shielding regions of the copper coating. By virtue of the additional low-resistance linking of the LED, it is possible to achieve a smaller voltage drop at the terminals.

In accordance with one embodiment, in each case exactly one shielding region is assigned to each intermediate surface or each light-emitting diode. This allows consistent shielding of the light of the light-emitting diodes.

In accordance with one embodiment, the shielding region is at a distance from at least one of the contact zones, specifically preferably within the intermediate surface or below the light-emitting diode. It is advantageously at a distance from only one of the two contact zones. This typically has the effect that a respectively non-conductive region, for example having a width of between 0.1 mm and 1 mm or even 2 mm, is formed between the copper coating in the form of the shielding regions and the contact zones. In particular, a short circuit or undesired electrical contact is thus prevented. Moreover, the provision of such a distance or non-conductive region can be advantageous for a soldering method for fixing the light-emitting diodes. The shielding region can be spaced apart from one contact zone and can be electrically connected to the other contact zone, such that the potential of the contact zone is defined by the shielding region. By way of example, one of the two contact zones, to which contact zone a single light-emitting diode is connected, can be earthed via the shielding region and the copper coating. Typically, all the LEDs of a display device are connected to the same potential by one contact zone in each case, usually the anode. This potential is present at the shielding surface composed of copper. All the LEDs are connected equivalently subject to the geometrical configuration chosen.

In accordance with one preferred embodiment, the shielding regions are formed in a tongue-like fashion or as projections, wherein preferably at least some tongue-like shielding regions have a free end. This corresponds to a geometrically simple embodiment which can easily be realized and in which a distance from the contact zones can also be achieved in a simple manner.

In accordance with one embodiment, the shielding regions extend along a respective longitudinal direction which is aligned transversely with respect to a longitudinal direction of the respective light-emitting diode arranged thereabove. In this case, preferably the shielding regions run straight. This likewise corresponds to an embodiment which can be realized in a geometrically simple manner.

It should be understood that indications such as “above”, “thereabove”, “below” or “therebelow” within the meaning of this application relate to a spatial orientation in which the printed circuit board is aligned in a horizontally level manner and the light-emitting diodes are arranged at the top above the printed circuit board. In order to simplify the description, reference is typically made to this state in the case of such positional indications, wherein the respectively corresponding positional indications are easily identifiable in the case of a different spatial orientation.

The copper coating preferably has at least one planar region arranged outside the intermediate surfaces. Here, the shielding regions are electrically connected to at least one planar region in each case. Such planar regions can be used for example for a large-area covering of the printed circuit board. By way of example, light can thus be prevented from emerging from the printed circuit board. Moreover, the printed circuit board can be connected to earth or some other defined electrical potential by means of the planar regions.

The shielding regions are preferably electrically connected to at least one planar region or the largest part of the copper coating on one side or on two sides. It is thus possible to achieve a potential equalization between planar regions and shielding regions. Here, the shielding regions can be formed in particular integrally with at least one planar region in each case. This facilitates a simple printed circuit board design and simple production.

In accordance with one preferred embodiment, the shielding regions are formed as protuberances or projections from at least one planar region in each case. This allows the shielding regions to be directly connected to a planar region in each case.

Advantageously, a shielding region, subject to cutouts, is at least of the same size as the internal dimensioning of an abovementioned luminous cap or light channel which can be arranged thereabove. If possible, the shielding regions are larger in order that light that is incident nevertheless can no longer emerge again from the printed circuit board at all or can emerge again therefrom only in a distributed manner and thus more weakly.

It should be mentioned that copper coatings can often be found on printed circuit boards anyway and corresponding production steps have to be performed in the context of printed circuit board production anyway. Accordingly, the provision of the shielding regions of a copper coating according to the invention generally produces only negligible or no additional costs.

The shielding regions are preferably spaced apart from the respective light-emitting diodes arranged thereabove, for example at a distance of 0.1 mm to 1 mm.

The copper coating is preferably earthed or is electrically connected to a unit that supplies a defined electrical potential, preferably at least at the shielding regions. This avoids regions having an undefined potential which can possibly be electrically charged and can thus disturb the function of the printed circuit board.

The light-emitting diodes are preferably embodied in accordance with Surface Mounted Device (SMD) technology and mounted thus on the printed circuit board. This allows a simple and cost-effective production method.

The shielding regions are preferably designed to reduce or prevent penetration of light emitted from the light-emitting diodes towards the printed circuit board into the printed circuit board. The undesired optical effects described in the introduction are thus avoided or prevented.

The shielding regions are preferably formed such that they are electrically non-functional, even if they are connected to earth or high level. An electrically non-functional embodiment should be understood to mean, in particular, that they are not used for purposes of electrical supply of a light-emitting diode or some other electrical consumption. Therefore, they are not present owing to an electrical function or are not designed for that, but rather are only formed from copper because it is non-transmissive to light. This enables an exact adaptation of the shielding regions to the function thereof intended here, which consists in reducing or preventing the penetration of light.

In accordance with one embodiment, a display cap or luminous cap mentioned above is arranged above each light-emitting diode, which cap forms or connects a light channel for light emitted by the light-emitting diode. The symbolism can then be produced in a luminous manner at the top. This allows a defined guiding of light to a desired position at which the light is intended to be visible to a user. It additionally allows a shielding from propagation of light transversely with respect to a desired light propagation direction.

In accordance with one embodiment, the display device comprises a number of seven-segment displays, wherein each seven-segment display comprises seven light-emitting diodes. This corresponds to a particularly suitable form of display for displaying numbers. An additional eighth light-emitting diode can illuminate a point thereon. On such a display, even more light-emitting diodes can of course be provided for individual symbols or the like.

The invention can be used, in principle, in all display devices comprising light-emitting diodes and light channels or luminous caps. The use is dependent on the possible printed circuit board design. Printed circuit board designs which permit large shielding regions are preferred. Advantageously, many or possibly even all of the light-emitting diodes of a display device can be connected in each case to the same potential, such that this potential can be distributed or connected via the shielding surface.

These and further features are evident not only from the claims but also from the description and the drawings, wherein the individual features can be realized in each case by themselves or as a plurality in the form of subcombinations in an embodiment of the invention and in other fields and can constitute advantageous and inherently protectable embodiments for which protection is claimed here. The subdivision of the application into intermediate headings and individual sections does not restrict the statements made thereunder in terms of their general validity.

### BRIEF DESCRIPTION OF THE SEVERAL VIEWS OF THE DRAWINGS

Further advantages and aspects of the invention are evident from the claims and from the following description of a preferred exemplary embodiment of the invention, which is explained below with reference to the figures, in which:

FIG. 1 shows a printed circuit board for a display device;

FIG. 2 shows the printed circuit board from FIG. 1 in an enlarged view;

FIG. 3 shows the printed circuit board from FIG. 2 with placed LEDs; and

FIG. 4 shows the display device from FIG. 3 in a sectional view.

### DETAILED DESCRIPTION

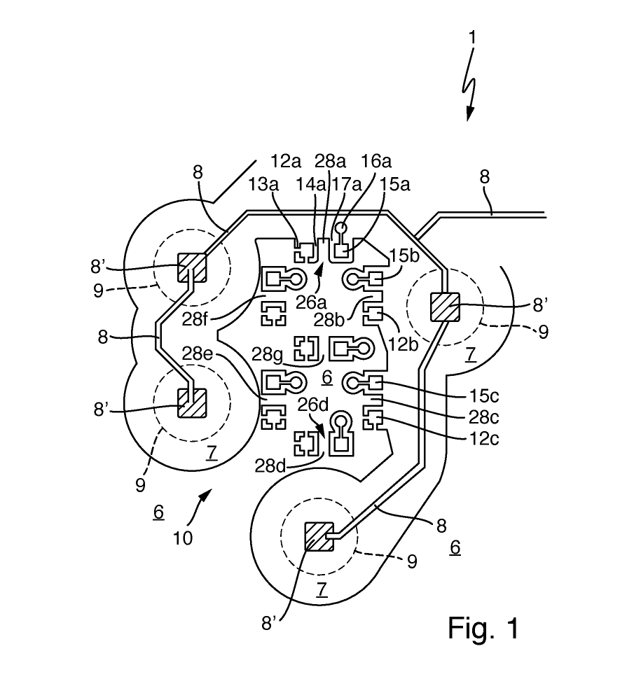

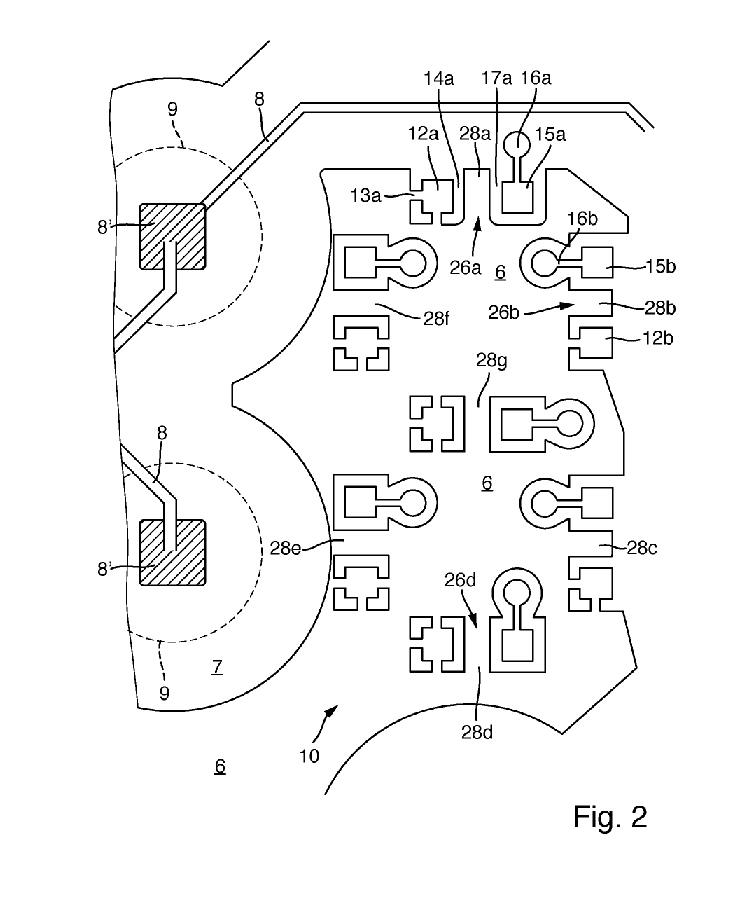

FIG. 1 shows schematically and FIG. 2 shows a central segment in an enlarged view of a display device 1 such as can be arranged in a hob below an operator interface, in particular the hob plate composed of glass ceramic. The display device 1 comprises a printed circuit board 5, which in the present case is formed from a material containing optical fibres. The printed circuit board has an upper copper coating 6 and a lower copper coating (not illustrated), as is known. A seven-segment display 10 is arranged on the printed circuit board 5. For electrically connecting the seven-segment display, structures or free regions 7 are worked, specifically usually etched, from the upper copper coating 6 and, if appropriate, also from the lower copper coating.

In addition, on the printed circuit board 5 of the display device 1, touch switches are also provided for a combined operating unit. For this purpose, relatively thin sensor conductor tracks 8a are provided, which pass to sensor contact zones 8′. Here, in turn sensor elements 9 illustrated by dashed lines are mounted on said sensor contact zones, wherein the electrical connection is produced only by means of the bearing contact or by means of a conductive adhesive. The sensor elements 9 can be larger or else smaller than the sensor contact zones 8′. This production of the electrical connection is known from U.S. Pat. No. 5,917,165 A, to which reference is explicitly made in this regard. Alternatively, differently designed electrically conductive sensor elements composed of elastic material can be provided, in particular also in continuous structures.

The seven-segment display 10 is intended precisely to have seven LEDs or connection possibilities for the latter. These are formed in a known manner by approximately rectangular or square zones of the copper coating 6, namely first contact zones 12a-g and second contact zones 15a-g. The first contact zones 12a-g are all electrically connected to the upper copper coating, specifically via contact bridges 13a-g that respectively bridge the trench 14a-g separating the first contact zones 12a-g from the rest of the copper surface. In a clearly discernible manner, one to three contact bridges 13a-g can be provided per first contact zone, depending on the geometrical conditions and space.

The second contact zones 15a-g are likewise separated from the rest of the copper coating 6 via trenches 17a-g, which in part have a different shape, however. The second contact zones 15a-g have contact bridges 16a-g that are designed differently. They extend a short way on the printed circuit board 5 and are then through-contacted on the underside thereof, however, usually by means of a through hole which, in the form of a plated-through hole, can be copper-lined and/or can be tin-plated in accordance with the surface of the contact zones. Therefore, the trenches 17a-g are also designed somewhat differently. In this case, the trenches 14a-g and 17a-g are provided for isolating the electrical potentials. In order to prevent soldering tin from flowing out to adjacent copper surfaces during SMD soldering, solder resist is typically used.

Intermediate surfaces 26a-g are provided between the contact zones 12a-g and 15a-g. According to the invention, now the upper copper coating 6 here as far as possible for electrical reasons, as shielding region 28a-g mentioned above, is drawn between the two contact zones or below the LED that is applied later. The shielding regions 28d-g must be at a distance from the contact zones 12a-g and 15a-g corresponding to the trenches 14a-g and 17a-g, otherwise the problems mentioned above arise during SMD soldering. The shielding regions 28d-g are continuous throughout and merge into the copper coating at both ends. They are thus at the potential of said copper coating, usually at high level, under certain circumstances at earth, but this does not produce any disturbance. Primarily, however, they thus shield the surface of the printed circuit board 5 from undesired entry of light from above through the LED. Normally, here in the intermediate regions the copper coating 5 would likewise be removed and the surface of the printed circuit board would be exposed, such that light can be coupled in undesirably as explained in the introduction with precisely those negative consequences.

By contrast, the shielding regions 28a-c are formed as elongate tongues having free ends. They cannot be longer owing to the small distance from the sensor conductor tracks 8a or the sensor elements 9 themselves. These need a particularly large distance from other signal lines or earth, in order to avoid coupled-in interference. The tongue-shaped shielding region 28b is even shorter still than the other two; it does not even extend over the entire width that is subsequently covered by the LED. That is owing to the required distance from the sensor element 9, which is indeed mandatory and relative to which the possible coupling-in of light of the LED into the printed circuit board 5 must be subordinate. Therefore, the shielding region 28b even extends only over somewhat more than half the width of the LED.

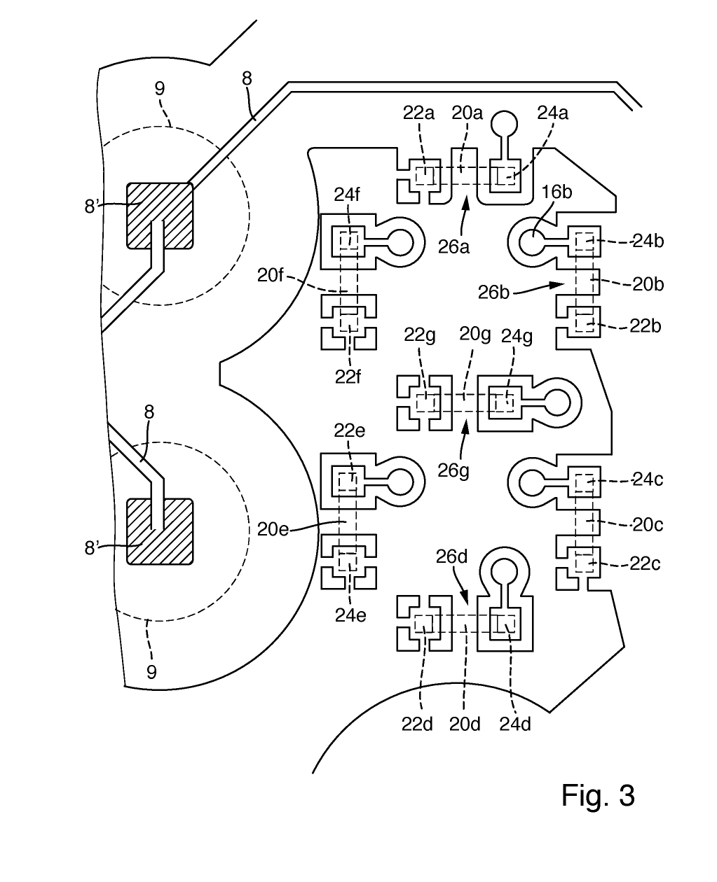

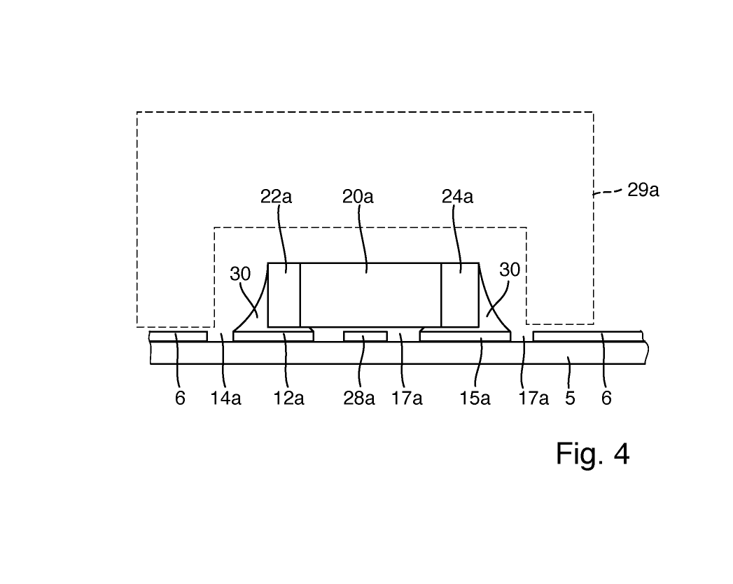

In FIG. 3, in comparison with FIG. 2, the LEDs 20a-g are now illustrated by dashed lines. The illustration by dashed lines is for the sake of clarity. The LEDs 20a-g are designed as entirely customary SMD LEDs and in each case have terminals 22a-g and 24a-g at the ends. With these terminals 22a-g and 24a-g they are soldered on the contact zones 12a-g and 15a-g in a customary SMD method using soldering tin 30. This is shown by FIG. 4 in lateral section for the LED 20a, where the trenches 14a and 17a running around the contact zones 12a and 15a can also be discerned. The contact bridges 13a and 16a are not illustrated here.

The LED 20a can bear on the shielding region 28a, which does not produce any disturbance electrically. In this regard, it could even dissipate waste heat better.

Above the LED 20a, a display cap 29a is illustrated by dashed lines as a luminous cap mentioned above. The latter can make the light of the LED 20a more uniform and, if appropriate, also provide it with a symbol representation. It can likewise prevent a lateral emergence of light from the LED 20a, which would lead to undesired luminous effects that would be visible from above. The display cap 29a can be designed for example in accordance with U.S. Pat. No. 8,506,131 B.

That which is claimed:

1. A display device comprising:
a printed circuit board comprising a structured copper coating, on which said structured copper coating a number of contact zones are defined; and
a number of light-emitting diodes comprising in each case a first terminal and a second terminal,
wherein said light-emitting diodes are mounted and electrically connected on said printed circuit board in such a way that each said terminal is fixed to a respectively assigned contact zone,
wherein an intermediate surface of said printed circuit board is formed between respectively two contact zones to which said two terminals of one said single light-emitting diode are fixed, said intermediate surface being covered by said light-emitting diode, and
wherein said copper coating comprises a number of shielding regions which at least partly cover one said intermediate surface in each case.

2. The display device according to claim 1, wherein in each case exactly one said shielding region is assigned to each said intermediate surface.

3. The display device according to claim 1, wherein said copper coating is spaced apart from said contact zones.

4. The display device according to claim 3, wherein said copper coating is spaced apart from said contact zones within said intermediate surface or below said light-emitting diode.

5. The display device according to claim 1, wherein said shielding regions are formed in a tongue-like fashion or as projections.

6. The display device according to claim 5, wherein at least some said tongue-like shielding regions have a free end.

7. The display device according to claim 1, wherein said shielding regions extend along a respective longitudinal direction which is aligned transversely with respect to a longitudinal direction of said respective light-emitting diode arranged thereabove.

8. The display device according to claim 7, wherein said shielding regions run straight.

9. The display device according to claim 1, wherein said copper coating comprises at least one planar region arranged outside said intermediate surfaces, wherein said shielding regions are electrically connected to at least one said planar region in each case.

10. The display device according to claim 9, wherein said shielding regions are electrically connected to at least one said planar region of said copper coating on one side or on two sides.

11. The display device according to claim 9, wherein said shielding regions are formed integrally with at least one said planar region in each case.

12. The display device according to claim 9, wherein said shielding regions are formed as protuberances or projections from at least one said planar region in each case.

13. The display device according to according to claim 1, wherein said shielding regions are spaced apart from said respective light-emitting diodes arranged thereabove.

14. The display device according to claim 1, wherein said copper coating is earthed or is electrically connected to a unit that supplies a defined electrical potential.

15. The display device according to claim 1, wherein said copper coating is earthed or is electrically connected to a unit that supplies a defined electrical potential at least at said shielding regions.

16. The display device according to claim 1, wherein said light-emitting diodes are mounted on said printed circuit board by means of Surface Mounted Device (SMD) technology.

17. The display device according to claim 1, wherein said shielding regions are designed to reduce or prevent penetration of light emitted from said light-emitting diodes towards said printed circuit board into said printed circuit board.

18. The display device according to claim 1, wherein said shielding regions are formed such that they are electrically non-functional.

19. The display device according to claim 1, wherein a display cap is arranged above each said light-emitting diode, wherein said display cap forms or connects a light channel for light emitted by said light-emitting diode.

20. The display device according to claim 1, wherein said display device comprises a number of seven-segment displays, wherein each said seven-segment display comprises seven of said light-emitting diodes.
